(19) United States
(12) Patent Application Publication
(10) Pub. No.: US 2018/0130526 A1
(43) Pub. Date: May 10, 2018

(54) METHOD FOR REFRESHING MEMORY CELLS AND MEMORY SYSTEM

(71) Applicant: SK hynix Inc., Gyeonggi-do (KR)

(72) Inventors: Do-Sun HONG, Gyeonggi-do (KR); Yong-Ju KIM, Seoul (KR); Dong-Gun KIM, Gyeonggi-do (KR)

(21) Appl. No.: 15/661,087

(22) Filed: Jul. 27, 2017

(30) Foreign Application Priority Data
Nov. 9, 2016 (KR) 10-2016-0148823

(51) Int. Cl. G11C 13/00

(52) U.S. Cl. CPC G11C 13/0004; G11C 13/0069; G11C 13/004

(57) ABSTRACT

A method for refreshing memory cells includes: reading data from a plurality of memory cells; and performing a write operation with a first data onto memory cells from which the first data is read among the plurality of memory cells.

### CROSS-REFERENCE TO RELATED APPLICATIONS

The present application claims priority of Korean Patent Application No. 10-2016-0148823, filed on Nov. 9, 2016, which is incorporated herein by reference in its entirety.

### BACKGROUND

1. Field

Exemplary embodiments of the present invention relate to a memory device and, more particularly, to a refresh operation of a memory device.

2. Description of the Related Art

Recently, the next-generation memory devices are being researched and developed to replace Dynamic Random Access Memory (DRAM) devices and flash memory devices. Among the next-generation memory devices is a resistive memory device using a variable resistance material whose resistance level drastically changes according to a bias applied thereto so that the resistance of the material may become one of two different resistance states. Non-limiting examples of the resistive memory device include a Phase-Change Random Access Memory (PCRAM), a Resistive Random Access Memory (RRAM), a Magnetic Random Access Memory (MRAM), a Ferroelectric Random Access Memory (FRAM) and the like.

A resistive memory device may typically have a memory cell array of a cross-point array structure. In the cross-point array structure, memory cells are disposed at cross-points formed by a plurality of lower electrodes (e.g., a plurality of row lines (word lines)) and a plurality of upper electrodes (e.g., a plurality of column lines (bit lines)). Each memory cell has a serially coupled resistance variable device and a selection device.

After data is written in a memory cell of a resistive memory device, the data may be lost due to a drift phenomenon that changes the resistance value of the resistive memory device as time passes.

### SUMMARY

Embodiments of the present invention are directed to a technology for effectively refreshing a resistive memory device before data stored therein is lost.

In accordance with an embodiment of the present invention, a method for refreshing memory cells includes: reading data from a plurality of memory cells; and performing a write operation with a first data onto memory cells from which the first data is read among the plurality of memory cells.

In accordance with another embodiment of the present invention, a method for refreshing memory cells includes: reading data from a plurality of memory cells; detecting and correcting an error data of the read data into an error-corrected data; deciding to perform a write operation onto memory cells from which a first data is read among the plurality of memory cells and deciding to perform the write operation onto a memory cell from which the error data is detected among the plurality of memory cells; and performing the write operation onto memory cells that the write operation is decided to be performed.

In the performing of the write operation onto the memory cells that the write operation is decided to be performed, a corrected data is written in the memory cell from which the error bit is read, and the first data is written in the memory cells other than the memory cell from which the error bit is read.

Each of the memory cells may include: a resistive e y element; and a selection element.

The resistive memory device May be a phase-change memory element.

The selection element may be an Ovonic Threshold Switch (OTS).

The first data may be a set data.

In accordance with yet another embodiment of the present invention, a memory system includes: a resistive memory device; and a memory controller suitable for controlling the resistive memory device, wherein, during a refresh operation of the resistive memory device, the memory controller reads data from a plurality of memory cells and performs a write operation with a first data onto memory cells from which the first data is read among the plurality of memory cells.

During the write operation, the memory controller may transfer the data that is read from the memory cells, and mask the memory cells from which the second data is read.

Each of the memory cells may include: a resistive memory element; and a selection element.

The resistive memory device may be a phase-change memory device, and the selection element may be an Ovonic Threshold Switch (OTS) device.

The first data may be a set data, and the second data may be a reset data.

In accordance with still another embodiment of the present invention, a memory system including: a resistive memory device; and a memory controller suitable for controlling the resistive memory device, wherein, during a refresh operation of the resistive memory device, the memory controller reads data from a plurality of memory cells, detects and corrects an error data of the read data into an error-corrected data, performs a write operation onto memory cells from which a first data is read and onto a memory cell from which the error data is read.

During the write operation, the error-corrected data may be written in the memory cell from which the error data is read, and the first data may be written in the memory cells other than the memory cell from which the error bit is read.

The memory controller may perform the write operation with the first data and the error-corrected data by writing the read data, which is error-corrected, into the plurality of memory cells while masking memory cells storing data other than the first data and the error data among the plurality of memory cells.

Each of the memory cells may include: a resistive memory element; and a selection element.

The resistive memory device may be a phase-change memory device, and the selection element may be an Ovonic Threshold Switch (OTS).

The data may be a set data.

### BRIEF DESCRIPTION OF THE DRAWINGS

FIG. 1 illustrates a memory cell of a memory device.

FIG. 2 is a graph illustrating a current-voltage (I-V) curve of the memory cell of FIG. 1.

FIGS. 3A and 3B are graphs illustrating threshold voltage distributions of the memory cells of a memory device.

FIG. 4 is a flowchart illustrating a method for refreshing memory cells in accordance with an embodiment of the present invention.

FIG. 5 a flowchart illustrating a method for refreshing memory cells in accordance with another embodiment of the present invention.

FIG. 6 is a block diagram illustrating a memory system in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

It is noted that the drawings are simplified schematics and as such are not necessarily drawn to scale. In some instances, various parts of the drawings may have been exaggerated in order to more clearly illustrate certain features of the illustrated embodiments.

It is further noted that in the following description, specific details are set forth for facilitating the understanding of the present invention, however, the present invention may be practiced without some of these specific details. Also, it is noted, that well known structures and/or processes may have only been described briefly or not described at all to avoid obscuring the present disclosure with unnecessary well known details.

It is also noted, that in some instances, as would be apparent to those skilled in the relevant art, an element (also referred to as a feature) described in connection with one embodiment may be used singly or in combination with other elements of another embodiment unless specifically indicated otherwise.

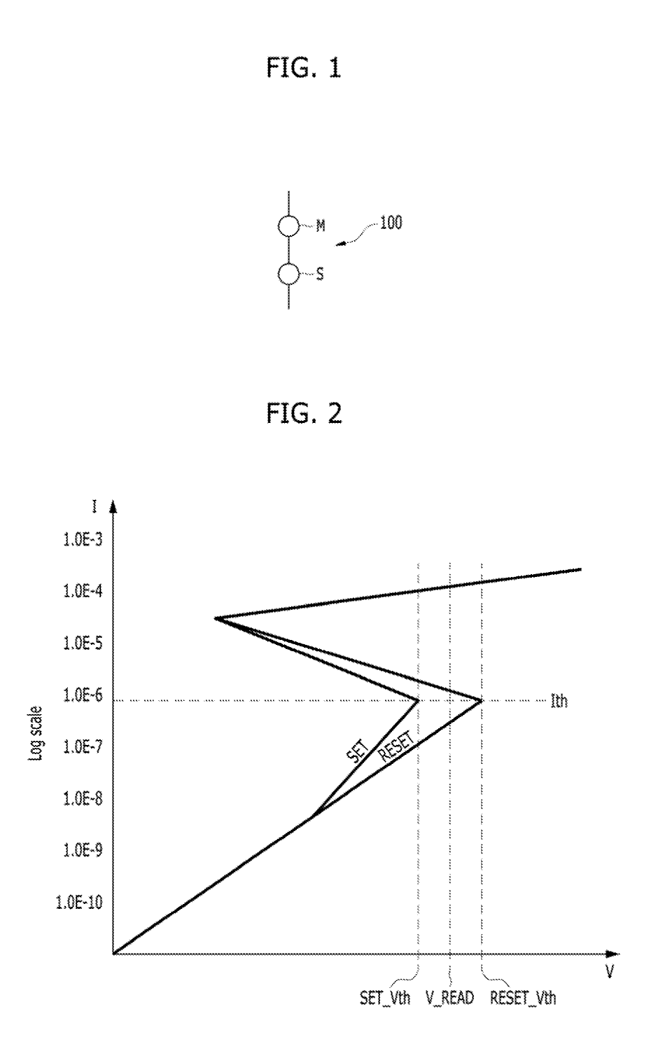

FIG. 1 illustrates a memory cell 100 of a resistive memory device. FIG. 2 is a graph showing a current-voltage (I-V) curve of the memory cell 100.

Referring to FIG. 1, the memory cell 100 may include a resistive memory device M and a selection device S.

The resistive memory device M may be in one of d low resistance state (a ‘set’ state) and a high resistance state (a ‘reset’ state) according to a stored data. In the case that the resistive memory device M is a Phase-Change (PC) memory device, a crystalline state thereof may represent the low resistance state and an amorphous state thereof may represent the high resistance state.

The selection device S has a slight amount of current flow when it is turned off. When the amount of current flowing through a memory cell is equal to or higher than a threshold value Ith, the selection device S is turned on so as to have much more current flow therethrough. After the selection device S is turned on, a snapback phenomenon may occur in the memory cell 100 where the voltage level at the ends of the memory cell 100 is drastically decreased. The selection device S may be an Ovonic Threshold Switch (OTS).

FIG. 2 shows current flowing through the memory cell 100 as a function of the voltage applied to the ends of the memory cell 100. Regardless of whether the memory cell 100 is in a high resistance state (i.e., “RESET” state in FIG. 2) or a low resistance state (i.e., “SET” state in FIG. 2), the amount of current flowing through the memory cell 100 increases, as the level of the voltage applied to both ends of the memory cell 100 increases. At the same voltage level, more current may flow through the memory cell 100 in the low resistance state (SET) than in the high resistance state (RESET).

When the voltage level at the ends of the memory cell 100 in the low resistance state (SET) reaches a threshold value SET_Vth of the low resistance state (SET) and thus the amount of current flowing through the memory cell 100 in the low resistance state (SET) reaches the threshold value Ith, the selection device S of the memory cell 100 in the low resistance state (SET) is turned on. The turned on selection device S of the memory cell 100 in the low resistance state (SET) drops the voltage level at the ends of the memory cell 100 and causes a drastic increase in the amount of current flowing through the memory cell 100, which is referred to as the snapback phenomenon.

When the voltage level at the ends of the memory cell 100 in the high resistance state (RESET) reaches a threshold value RESET_Vth of the high resistance state (RESET) and thus the amount of current flowing through the memory cell 100 in a high resistance state (RESET) reaches the threshold value Ith, the selection device S of the memory cell 100 in the high resistance state (RESET) is turned on. The turned on selection device S of the memory cell 100 in the high resistance state (RESET) drops the voltage level at the ends of the memory cell 100 and causes a drastic increase in the amount of current flowing through the memory cell 100, which is also referred to as a snapback phenomenon.

Stored data may be read from the memory cell 100 through the snapback phenomenon. In a case where a read voltage V_READ, which is higher than the threshold value SET_Vth of the low resistance state and lower than the threshold value RESET_Vth of the high resistance state, is applied to the ends of the memory cell 100, the snapback phenomenon occurs in the memory cell 100 not in the high resistance state (RESET) but in the low resistance state (SET) and thus a great deal of current flows through the memory cell 100 not in the high resistance state (RESET) but in the low resistance state (SET). The snapback phenomenon will not occur when the memory cell 100 is in the high resistance state (RESET) and thus a small amount of current may flow through the memory cell 100. Therefore, it is possible to know whether the memory cell 100 is in a low resistance state (SET) or a high resistance state (RESET) by applying the read voltage V_READ to the ends of the memory cell 100 and sensing the amount of current flowing through the memory cell 100, or stated otherwise observing whether or not the snapback phenomenon occurs.

The data may be written (programmed) into the resistive memory cell 100 by applying a write current to the resistive memory cell 100 in order for the resistive memory device M of the memory cell 100 to enter a melting state. Then, by slowly decreasing the write current after the resistive memory device M of the resistive memory cell 100 goes into the melting state, the state of the resistive memory device M changes into the crystalline state which is the low resistance state. Alternatively, when the write current is rapidly decreased after the resistive memory device M of the resistive memory cell 100 goes into the melting state, the state of the resistive memory device M changes into the amorphous state which is the high resistance state.

The resistance value of the resistive memory device M of the resistive memory cell 100 may be changed due to a drift phenomenon as time passes. Also, it is known that the resistance value of the selection device S may be changed due to the drift phenomenon as time passes and the data stored in the resistive memory cell 100 may get lost due to the drift phenomenon.

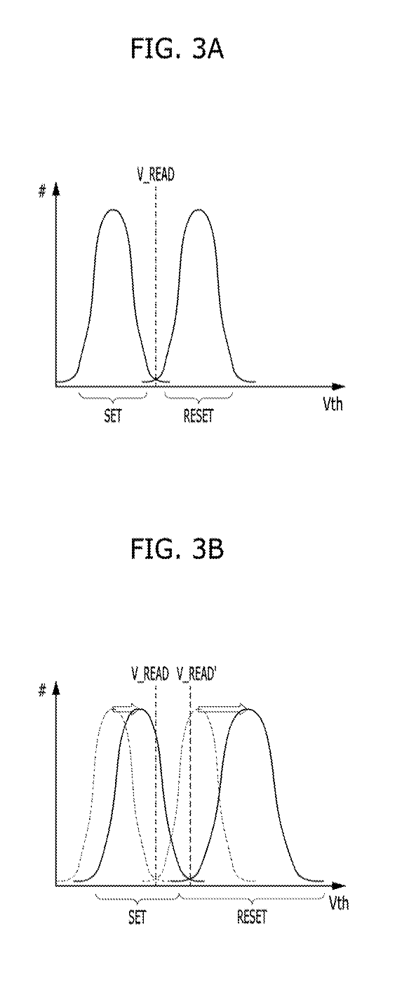

FIGS. 3A and 3B are graphs illustrating threshold voltage distributions of the memory cells of the resistive memory device.

FIG. 3A shows threshold voltage Vth distributions of the memory cells right after data is written. The X axis represents the threshold voltage Vth, and the Y axis represents the number of memory cells. When the threshold voltage Vth distributions of the memory cells in the set and the reset states are clearly separated, as shown in FIG. 3A, the memory cells of the set state SET and the memory cells of the reset state RESET may be distinguished from each other using a read voltage V_READ as shown in FIG. 3A.

FIG. 3B shows threshold voltage Vth distributions of the memory cells illustrating the drift phenomenon which occurs in the set and reset states of the memory cells after a predetermined time passes from the moment of FIG. 3A. Referring to FIG. 3B, all the threshold voltage values of the memory cells of the set state SET and the memory cells of the reset state RESET are increased due to the drift phenomenon. When the drift phenomenon occurs, the memory cells of the set state SET and the memory cells of the reset state RESET have to be distinguished from each other based on a read voltage V_READ′ which is higher than the read voltage V_READ of FIG. 3A. Although a drift of all the threshold voltage values have a tendency of increasing as time passes, each amount of drift of the threshold voltage values for the set state SET and the reset state RESET may not be the same. Therefore, it is very difficult to appropriately control the value of the read voltage V_READ′ and thus the data stored in at least some of the memory cells may get lost due to excessive drift.

In particular, since the threshold resistance value of the memory cells is increased due to the drift phenomenon, a problem may occur where the state of some of the memory cells which are in the set state SET is changed into a reset state RESET. The state of the memory cells which are in the reset state RESET is not changed into the set state SET due to the drift phenomenon.

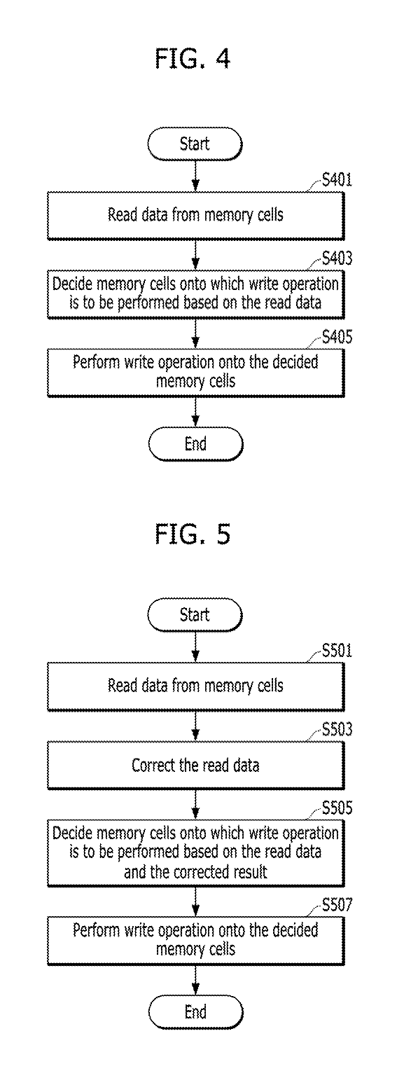

FIG. 4 is a flowchart illustrating a method for refreshing memory cells to prevent data loss in a resistive memory device due to the drift phenomenon in accordance with an embodiment of the present invention.

Referring to FIG. 4, in step S401, data may be read from a plurality of memory cells of a resistive memory device which are designated for a refresh operation.

In step S403, it may be decided based on the data read in step S401 for which of the designated memory cells a write operation may be performed. Specifically, a write operation may be performed only onto the memory cells which are in the set sate based on the read data i.e., memory cells for which the read data is data ‘0’. This is because only the set data may be lost as time passes due to the drift phenomenon. The reset data, as explained above cannot be lost due to the drift phenomenon.

In step S405, a write operation is performed in which the set data are written again in the memory cells from which the set data are read. Since the set data are re-written, the memory cells storing the set data are recovered from the drift.

If only reset data are read from the memory cells of the resistive memory device in the step S401. then a refresh operation need not be performed on the memory cells.

According to the refresh operation shown in FIG. 4, data may be rewritten only into the memory cells storing set data among the memory cells while reset data may not be rewritten into the memory cells storing the reset data. In short, an unnecessary rewrite operation may be prevented and thus the total amount of current consumed for the refresh operation may be reduced. Further, since the number of the rewrite operations is reduced, the lifespan of the memory cells may be increased. Also, the time employed for the performance of the refresh operation may be reduced.

FIG. 5 is a flowchart illustrating a method for refreshing memory cells in accordance with another embodiment of the present invention. FIG. 5 shows a case where an error is corrected during a refresh operation.

Referring to FIC. 5, in step S501, data may be read from the memory cells onto which a refresh operation is to be performed. As an example, it is assumed that a data ‘10101010’ is read from eight memory cells.

In step S503, the read data may be corrected, by detecting an error bit, and correcting the error bit. This error-correction operation may be performed by an Error Correction Code (ECC) circuit. For example, an error may be detected from a second Least Significant Bit (LSB) of the read data ‘10101010’, and the detected error may be corrected to ‘10101000’.

In step S505, memory cells onto which a write operation is to be performed may be decided based on the read data from step S501. Specifically, a write operation may be performed onto the memory cells from which set data (i.e., data ‘0’) are read in the step S501. This is because only the set data may be lost due to the drift phenomenon.

In step S505, the execution of the write operation for a memory cell from which an error bit is detected (which is the memory cell storing the second LSB) may be decided. This is because the error is corrected and the logic value of the data is changed. Hence, in the case where a memory cell for which an error bit is detected, whether a ‘0’ data is corrected into a ‘1’ data or whether a ‘1’ data is corrected into a ‘0’ data, the corrected data should be written again.

In step S507, the write operation may be performed again to the memory cells onto which the write operation is decided to be executed in the step S505. Among the memory cells onto which the write operation is decided to be executed, the error-corrected data may be written in the memory cell from which the error bit is detected, and the set data (i.e., data ‘0’) may be written in the memory cells from which the set data is read. After all, among the eight memory cells where the data ‘10101010’ is stored, ‘X0X0X000’ may be written in five memory cells. Herein, ‘X’ may represent that the write operation is not performed.

According to the refresh operation of FIG. 5, the write operation may be performed only onto the memory cells storing the set data (i.e., data ‘0’) and onto the memory cells for which an error bit is detected among the memory cells. In short, unnecessary rewrite operations may be prevented. Thus, the amount of current consumed for a refresh operation may be reduced. Further, since a number of the rewrite operations is reduced, the lifespan of the memory cells may be increased. Further the time for performing the refresh operation may also be reduced.

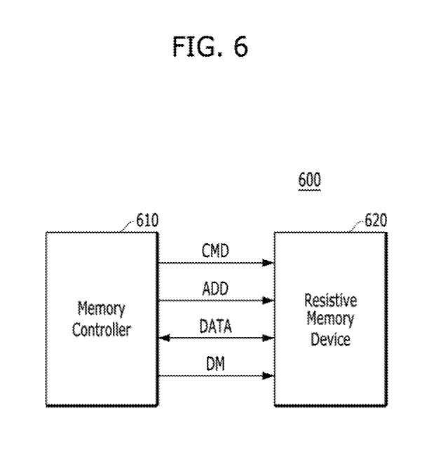

FIG. 6 is a block diagram illustrating a memory system 600 in accordance with an embodiment of the present invention.

Referring to FIG. 6 the memory system 600 may include a memory controller 610 and a resistive memory device 620.

The memory controller 610 may control the resistive memory device 620 to read data stored in the resistive memory device 620 and/or to program data into the resistive memory device 620. The memory controller 610 may further control the resistive memory device 620 to be refreshed according to the methods described above with reference to FIGS. 4 and/or 5. The memory controller 610 may control the resistive memory device 620 by applying a command CMD and an address ADD to the resistive memory device 620. Then, data DATA may be transferred between the memory controller 610 and the resistive memory device 620. During a read operation data DATA may be transferred from the resistive memory device 620 to the memory controller 610. During a write operation, data DATA may be transferred from the memory controller 610 to the resistive memory device 620. Meanwhile, a data mask signal DM may be transferred from the memory controller 610 to the resistive memory device 620. The data mask signal DM may be used to prevent some data from being written, that is, to mask some data, during a write operation.

The refresh operation described above with reference to FIGS. 4 and 5 may be performed in the memory system 600 as follows.

Refresh Operation of FIG. 4 to the Memory System 600

To perform step S401, the memory controller 610 may provide the resistive memory device 620 with a command CMD for a read operation and an address ADD for designating memory cells to which a refresh operation is to be performed. Then, data may be read from the designated memory cells of the resistive memory device 620, and the read data may be transferred to the memory controller 610. As an example, it is assumed herein that data ‘11001010’ is read from eight memory cells.

In the step S403, the memory controller 610 may decide to perform a refresh operation to the designated memory cells based on the read data. Since four bits of the data among the eight bits of the data are ‘0’, the write operation may be decided to be performed onto the four memory cells among the eight memory cells.

To perform step S405, the memory controller 610 may provide the resistive memory device 620 with a command CMD for a write operation and an address ADD which may be the same as the one provided in step S401. The memory controller 610 then may transfer the same data as the read data of step S401 to the resistive memory device 620 as write data. In order to write only ‘0’ data in the resistive memory device 620 among the transferred data, a data mask signal DM may be used. The memory controller 610 may mask all ‘1’ data among the write data. For example, the memory controller 610 may mask the ‘1’ data so that the ‘1’ data is not written among the write data by transferring the data mask signal DM of ‘00110101’ while transferring the write data of ‘11001010’. When the data mask signal DM has a value of ‘1’ the corresponding data may be written in the memory cells. When the data mask signal DM has a value of ‘0’, the corresponding data may not be written in the memory cells but masked.

Refresh Operation of FIG. 5 to Memory System

To perform the process of the step S501, the memory controller 610 may provide the resistive memory device 620 with a command CMD for a read operation and an address ADD for designating memory cells where a refresh operation is to be performed. Then, data may be read from the designated memory cells of the resistive memory device 620, and the read data may be transferred to the memory controller 610. As an example, it is assumed herein that data ‘10010001’ is read from eight memory cells.

The process of the step S503 may be performed by an ECC circuit (not shown) included in the memory controller 610. The ECC circuit may detect an error by using an error correction code ECC and correct the detected error. Herein, it is assumed that an error is detected in the third Most Significant Bit (MSB) of the read data ‘10010001’ and the read data is corrected into a data ‘10110001’.

In the step 5505, the memory controller 610 may decide to perform a refresh operation to the memory cells based on the read data of the step S501 and the error-corrected data of the step S503. Since five bits of the data among the eight bits of the data are ‘0’, the write operation may be decided to be performed onto the five memory cells among the eight memory cells. Also, the write operation may be decided to be performed onto the memory cell from which the erroneous third MSB is read in the step S503. Since the execution of the write operation to the memory cell from which the erroneous third MSB has been already decided on the basis that the erroneous third MSB is read as data ‘0’, it may be said that the write operation is decided to be performed onto the five memory cells after all.

To perform the process of the step S507, the memory controller 610 may provide the resistive memory device 620 with a command CMD for a write operation and an address ADD which is the same as that of the step S501. The memo controller 610 then may transfer the same data (which is ‘10110001’) as the error-corrected read data of the step S503 to the resistive memory device 620 as a write data. In order to write only a portion of the transferred data in the memory cells, a data mask signal DM may be used. The memory controller 610 may make only five bits of the transferred eight-bit write data written in the memory cells by transferring the data mask signal DM of ‘01101110’ while transferring the write data of ‘10110001’.

According to the embodiments of the present invention, memory cells may be efficiently refreshed.

While the present invention has been described with respect to the specific embodiments, it will be apparent to those skilled in the art that various changes and modifications may be made without departing from the spirit and scope of the invention as defined in the following claims.

What is claimed is:

1. A method for refreshing memory cells, comprising:
reading data from a plurality of memory cells; and
performing a write operation with a first data onto memory cells from which the first data is read among the plurality of memory cells.

2. The method of claim 1, wherein each of the plurality of memory cells includes:
a resistive memory element; and
a selection element.

3. The method of claim 2, wherein the resistive memory element is a phase-change memory element.

4. The method of claim 3, wherein the selection element is an Ovonic Threshold Switch (OTS).

5. A method for refreshing memory cells, comprising:
reading data from a plurality of memory cells;
detecting and correcting an error data of the read data into an error-corrected data;
deciding to perform a write operation onto memory cells from which a first data is read among the plurality of memory cells and deciding to perform the write operation onto a memory cell from which the error data is detected among the plurality of memory cells; and
performing the write operation onto memo cells that the write operation is decided to be performed.

6. The method of claim 5 wherein in the performing of the write operation onto the memory cells that the write operation is decided to be performed,
a corrected data is written in the memory cell from which the error bit is read, and the first data is written in the memory cells other than the memory cell from which the error bit is read.

7. The method of claim 5, wherein each of he plurality of memory cells includes:
a resistive memory element; and
a selection element.

8. The method of claim 7, wherein the resistive memory element is a phase-change memory element.

9. The method of claim 8, wherein the selection device is an Ovonic Threshold Switch OTS).

10. A memory system, comprising:
a resistive memory device; and
a memory controller suitable for controlling the resistive memory device,
wherein, during a refresh operation of the resistive memory device, the memory controller reads data from a plurality of memory cells and performs a write operation with a first data onto memory cells from which the first data is read among the plurality of memory cells.

11. The memory system of claim 10, wherein the memory controller performs the write operation with the first data by writing the read data into the plurality of memory cells while masking memory cells storing data other than the first data among the plurality of memory cells.

12. The memory system of claim 10, wherein each of the plurality of memory cells includes:
a resistive memory element; and
a selection element.

13. The memory system of claim 12,
wherein the resistive memory device is a phase-change memory element, and
wherein the selection device is an Ovonic Threshold Switch (OTS).

14. A memory system, comprising:
a resistive memory device; and
a memory controller suitable for controlling the resistive memory device,
wherein, during a refresh operation of the resistive memory device, the memory controller reads data from a plurality of memory cells, detects and corrects an error data of the read data into an error-corrected data, performs a write operation onto memory cells from which a first data is read and onto a memory cell from which the error data is read

15. The memory system of claim 14, wherein, during the write operation,
the error-corrected data is written in the memory cell from which the error data is read, and the first data is written in the memory cells other than the memory cell from which the error bit is read.

16. The memory system of claim 15, wherein the memory controller performs the write operation with the first data and the error-corrected data by writing the read data, which is error-corrected, into the plurality of memory cells while masking memory cells storing data other than the first data and the error data among the plurality of memory cells.

17. The memory system of claim 14, wherein each of the plurality of memory cells includes:
a resistive memory element; and
a selection element.

18. The memory system of claim 17,
wherein the resistive memory element is a phase-change memory element, and
wherein the selection device is an Ovonic Threshold Switch (OTS).
